(19) United States
(12) Patent Application Publication
(10) Pub. No.: US 2020/0241677 A1
(43) Pub. Date: Jul. 30, 2020

(54) POLARIZED LIGHT TOUCH DEVICE, METHOD FOR MANUFACTURING SAME AND FLEXIBLE DISPLAY DEVICE

(71) Applicant: Wuhan China Star Optoelectronics Semiconductor Display Technology Co., Ltd., Wuhan (CN)

(72) Inventor: Dan LIN, (US)

(21) Appl. No.: 16/492,158

(22) PCT Filed: Mar. 13, 2019
(86) PCT No.: PCT/CN2019/077944

§ 371 Date: Sep. 9, 2019

(30) Foreign Application Priority Data
Jan. 25, 2019 (CN) 201910074748.9

(51) Int. Cl. G06F 3/041; H01L 27/32; H01L 51/56

(52) U.S. Cl. CPC G06F 3/0412; H01L 27/323; H01L 51/56; H01L 2251/558; G06F 2203/04102; H01L 2251/5338; G06F 2203/04103

(57) ABSTRACT

The application provides a polarized light touch device, a manufacturing method, and a flexible display device, the polarized light touch device includes: a substrate, a polarizer layer, and a touch layer; the touch layer and the polarized layer get together to one piece structure as the polarized light touch device to omit an extra adhesive formed between the touch layer and the polarized light layer, to reduce an overall thickness of the flexible display device, and to make it more thinner.

### BACKGROUND OF INVENTION

### Field of Invention

The present invention relates to a display technology field, and particularly to a polarized light touch device, a method for manufacturing the polarized light touch device and a flexible display device.

### Description of Prior Art

Flexible active matrix organic light emitting diode (AMOLED) displays have advantages of high brightness, high color gamut, wide viewing angles and changeable appearance, and a display technique which has competitive advantages in the future. Referring to FIG. 1, a conventional flexible display module includes a flexible display panel 100, a touch screen 200, a polarizer 300, and a cover 400, the polarizer 300 includes a first bonding layer 301, a phase compensation film 302, a second bonding layer 303, a first isolation layer 304, a polyvinyl alcohol film 305, and a second isolation layer 306 formed as a stack-up, the touch screen 200 includes a substrate 201 and a touch layer 202, and the touch screen 200 and the polarizer 300 are connected by a third bonding layer 500, wherein bonding together by the OCA glue, so an overall thickness of display module is large.

Therefore, the overall thickness of the flexible display device in prior art needs to be reduced.

### SUMMARY OF INVENTION

The application provides polarized light touch device, a method for manufacturing the polarized light touch device and a flexible display device to solve a technical question of a large overall thick of a flexible display device.

In order to solve the above problem, the application provides as follow:

The application provides a polarized light touch device, which includes:

a substrate;

a polarized light layer formed on a first surface of the substrate;

a touch layer formed on a second surface of the substrate;

a first protective layer formed on a surface of the polarized light layer facing away from the substrate; and

a second protective layer formed on a surface of the touch layer facing away from the substrate.

In the polarized light touch device of the application, the polarized light layer includes a phase compensation film and a polarized light function film, the phase compensation film is formed on the substrate.

In the polarized light touch device of the application, the phase compensation film is a quarter wavelength film.

In the polarized light touch device of the application, the polarized light function film is polyvinyl alcohol film.

In the polarized light touch device of the application, the touch layer includes a connection region and an identification region, a plurality of touch electrodes are formed in the identification region, a plurality of connectors are formed in the connection region.

In the polarized light touch device of the application, the touch electrodes includes a plurality of driving electrodes and a plurality of induction electrodes, the driving electrodes and the induction electrodes are arranged in a same layer.

The application also provides a flexible display device, which includes:

a flexible display panel;

a polarized light touch device formed on a light direction of the flexible display panel; and

a protective cover;

wherein the polarized light touch device includes:

a substrate;

a polarized light layer formed on a surface of the substrate facing away from the flexible display panel;

a touch layer formed on a surface of the substrate facing the flexible display panel.

In the flexible display device of the application, the polarized light layer includes a phase compensation film and a polarized light function film, the phase compensation film is formed on the substrate.

In the flexible display device of the application, the phase compensation film is a quarter wavelength film.

In the flexible display device of the application, the polarized light function film is polyvinyl alcohol film.

In the flexible display device of the application, the touch layer includes a connection region and an identification region, a plurality of touch electrodes are formed in the identification region, a plurality of connectors are formed in the connection region.

In the flexible display device of the application, the touch electrodes includes a plurality of driving electrodes and a plurality of induction electrodes, the driving electrodes and the induction electrodes are arranged in a same layer.

In the flexible display device of the application, the flexible display device includes a flexible printed circuit board, the flexible printed circuit board includes driving chips, the driving chips are electrically connected to the connectors.

The application also provides a method for manufacturing a polarized light touch device, which includes:

providing a substrate;

forming a polarized light layer on a first surface of the substrate;

forming a first protective layer on a surface of the polarized light layer facing away from the substrate;

forming a touch layer on a second surface of the substrate; and

forming a second protective layer on a surface of the touch layer facing away from the substrate.

In the method for manufacturing the polarized light touch device of the application, a step of forming a polarized light layer on a first surface of the substrate includes:

coating a phase compensation film on the substrate;

coating an adhesive layer on the phase compensation film; and

coating a polarized light function film on the adhesive layer to form a polarized light layer.

In the method for manufacturing the polarized light touch device of the application, a step of coating a phase compensation film on the substrate includes:

coating a quarter wavelength film on the substrate.

In the method for manufacturing the polarized light touch device of the application, a step of coating an adhesive layer on the phase compensation film includes:

coating a pressure sensitive adhesive on the phase compensation film.

In the method for manufacturing the polarized light touch device of the application, a step of coating a polarized light function film on the adhesive layer includes:

coating a polyvinyl alcohol film on the adhesive layer.

In the method for manufacturing the polarized light touch device of the application, a step of forming a touch layer on a second surface of the substrate includes:

forming a connection region and an identification region on a second surface of the substrate;

forming a plurality of touch electrodes in the identification region; and

forming a plurality of connectors in the connection region.

In the method for manufacturing the polarized light touch device of the application, a step of forming a plurality of touch electrodes in the identification region includes:

forming a plurality of driving electrodes and a plurality of induction electrodes, wherein the driving electrodes and the induction electrodes are arranged in a same layer.

The beneficial effect of this invention is: the application provides a polarized light touch device, a method for manufacturing the polarized light touch device, and a flexible display device, the polarized light touch device includes a substrate; a polarized light layer formed on a first surface of the substrate; a touch layer formed on a second surface of the substrate; a first protective layer formed on a surface of the polarized light layer facing away from the substrate; and a second protective layer formed on a surface of the touch layer facing away from the substrate. The touch layer and the polarized layer get together to one piece structure as the polarized light touch device to omit an extra optical clear adhesive (OCA) formed between the touch layer and the polarized light layer, to reduce an overall thickness of the flexible display device, and to make it more thinner.

### BRIEF DESCRIPTION OF DRAWINGS

In order to more clearly illustrate the embodiments or the technical solutions in prior art, the drawings to be used in the embodiments or prior art description will be briefly described below. Obviously, the drawings in the following description are merely inventions. For some embodiments, other drawings may be obtained from those skilled in the art without any creative work.

FIG. 1 is a schematic view of a flexible display device in prior art.

FIG. 2 is a schematic view of a polarized light touch device of one embodiment of the application.

FIG. 3a is a schematic view of a touch layer of a polarized light touch device of one embodiment of the application.

FIG. 3b is a cross-sectional view of a touch layer of a polarized light touch device of one embodiment of the application.

FIG. 4 is a schematic view of a flexible display device of one embodiment of the application.

FIG. 5a is a schematic view of a touch layer of a polarized light touch device of a flexible display device of one embodiment of the application.

FIG. 5b is a cross-sectional view of a touch layer of a polarized light touch device of a flexible display device of one embodiment of the application.

FIG. 6 is a flowchart of a method for manufacturing a polarized light touch device of one embodiment of the application.

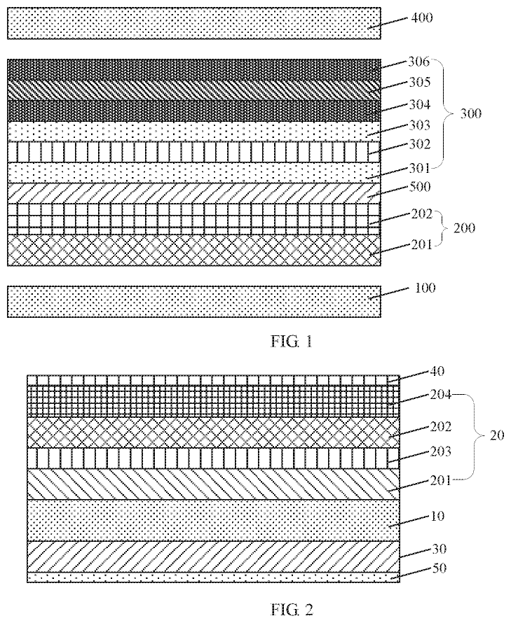

### DETAILED DESCRIPTION OF PREFERRED EMBODIMENTS

The technical solutions in the embodiments and/or the embodiments of the present application will be clearly and completely described in conjunction with the specific embodiments of the present application. It is obvious that the embodiments and/or embodiments described below are only partially implemented in this application. Schemes and/or embodiments, but not all embodiments and/or embodiments. All other embodiments and/or embodiments obtained by a person of ordinary skill in the art based on the embodiments and/or embodiments of the present application without prior inventive work are all within the scope of the present application.

Directional terms mentioned in this application, such as “top”, “bottom”, “left”, “right”, “front”, “back”, “inside”, “outside”, “side”, etc., are only references Attach the direction of the drawing. Therefore, the directional terminology used is for the purpose of illustration and understanding of the application. The terms “first”, “second” and the like are used for descriptive purposes only and are not to be understood as indicating or implying their relative importance or implicitly indicating the number of technical features indicated. Thus, features defining “first”, “second”, etc. may include one or more of the features, either explicitly or implicitly.

The application can alleviate the technical problem of a large overall thickness of a flexible display device in prior art.

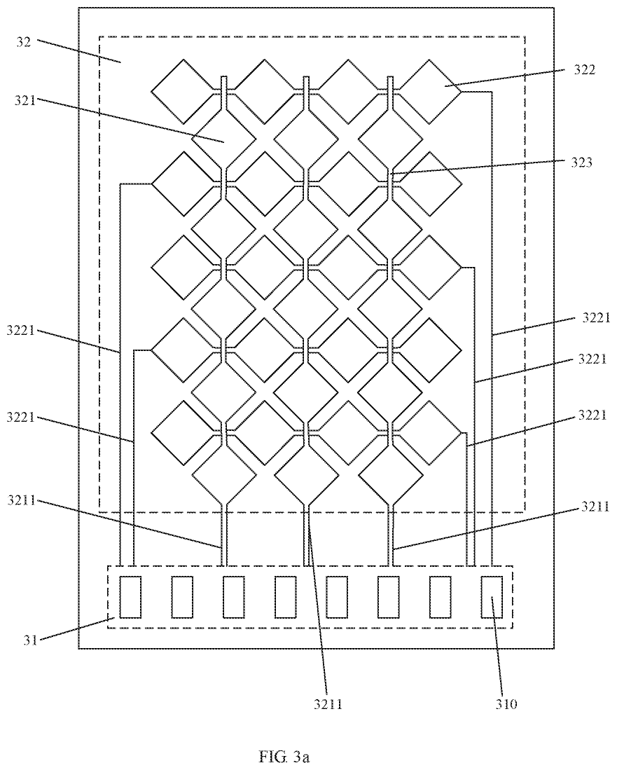

In one embodiment, referring to FIG. 2, the application provides a polarized light touch device including:

a substrate 10;

a polarizer layer 20 formed on the a surface of the substrate;

a touch layer 30 formed on a second surface of the substrate;

a first protective layer 40 formed on a surface of the polarized light layer facing away from the substrate; and

a second protective layer 50 formed a surface of the touch layer facing away from the substrate.

The application provides a polarized light touch device, the polarized light touch device includes a substrate; a polarized light layer formed on a first surface of the substrate; a touch layer formed on a second surface of the substrate; a first protective layer formed on a surface of the polarized light layer facing away from the substrate; and a second protective layer formed on a surface of the touch layer facing away from the substrate. The touch layer and the polarized layer get together to one piece structure as the polarized light touch device to omit an extra optical clear adhesive (OCA) formed between the touch layer and the polarized light layer, to reduce an overall thickness of the flexible display device, and to make it more thinner.

In one embodiment, the substrate 10 can be made of cyclo olefin polymers (COP) and polyethylene terephthalate (PET) etc. to ensure the polarized light touch device having a better bending characteristic.

In one embodiment, referring to FIG. 2, the polarizer layer 20 is formed on the first surface of the substrate 10 and includes a phase compensation film 201 and a polarizer function film 202, and the phase compensation film 201 is formed on the first surface of the substrate 10.

In one embodiment, referring to FIG. 2, the phase compensation film 201 is based on the substrate 10 and directly formed on the substrate 10 by a coating process, that is, the phase compensation film 201 is connected to the substrate 10 without a coating glue layer, but the phase compensation film 201 is directly formed on the substrate 10. The phase compensation film 201 is a quarter wavelength film.

The polarizer function film 202 plays a major role in polarizing in the polarizer layer 20, which determines a polarizing performance and transmittance of the polarizer layer 20, at the same time, the polarizer function film 202 is also a major part of affecting a tone and optical durability of the polarizing layer 20.

In one embodiment, referring to FIG. 2, the polarizer layer 20 further includes a bonding layer 203, the bonding layer 203 is formed on a side surface of the phase compensation film 201 facing away from the substrate 10, in this embodiment, the bonding layer 203 is made of a pressure sensitive adhesive, because the pressure sensitive adhesive has characteristics of low elastic modulus and high bending, it can be used to support and protect the polarizer function film 202.

In one embodiment, the polarizer function film 202 is a polyvinyl alcohol film. The polyvinyl alcohol film is formed by applying light alignment technique to arrange double absorption dye molecules and obtain a high D value, and then the dye molecules are coated on the bonding layer 203, a thickness of the polyvinyl alcohol film is less than 2 micrometers. Because the polarizer function film 202 is prepared by a coating method, the thickness of the film layer is obviously reduced compared with the prior polyvinyl alcohol by a stretching method.

Because the polyvinyl alcohol material is easy to absorb water and fade, so it needs to form a material with a good optical uniformity and transparency on one side surface of the polarizer function film 202 facing away from the bonding layer 203 to isolate water and air, to protect the polarizer function film 202, and to prevent the polarizer function film 202 from losing a polarizer performance due to water absorption and fading.

Therefore, in one embodiment, referring to FIG. 2, the polarizer layer 20 further includes an isolation layer 204, the isolation layer 204 is formed on one side surface of the polarizer function film 202 facing away from the bonding layer 203 to isolate water and air, and to protect the polarizer function film 202. In the present embodiment, the isolation layer 204 is made of cellulose triacetate.

In prior art, the polarizer function film is formed by stretching a polyvinyl alcohol to form a film, and then bonds to the phase compensation film, therefore, it is necessary to prepare an isolation layer on the upper and lower surfaces of the polarizer function film firstly to isolate water and air before bonding.

Compared with prior art, the polarized light touch device is provided by the application, as the polarizer function film 202 is formed by a coating method, so only needs to prepare an isolation layer on the upper surface after coating, that is, one isolation layer is reduced between the polarizer function film 202 and the phase compensation film 201; at the same time, the thickness of the polyvinyl alcohol film layer prepared by a coating method is significantly reduced than that of the polyvinyl alcohol film layer made by stretching, so as to achieve the overall thinning of the polarized light touch device.

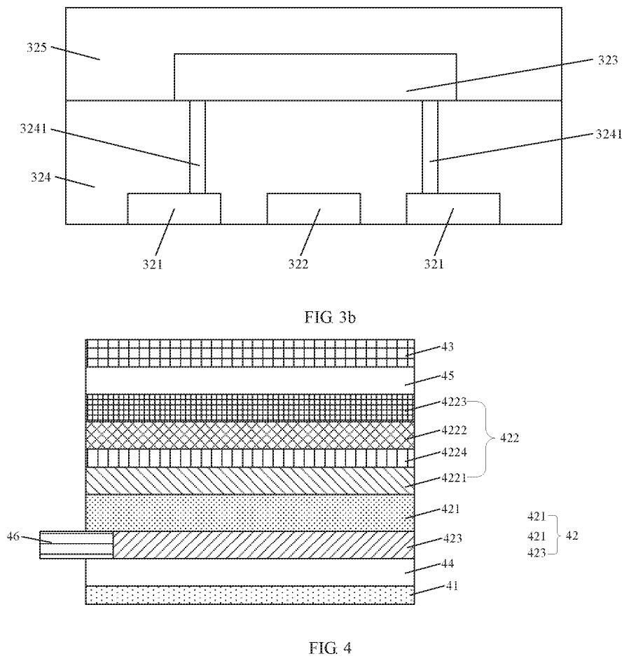

In one embodiment, referring to FIG. 2, the touch layer 30 is formed on the second surface of the substrate 10, and the specific structure of the touch layer 30 is shown in FIG. 3a and FIG. 3b.

In one embodiment, referring to FIG. 3a, the touch layer 30 includes a connection region 31 and an identification region 32, a plurality of connectors 310 are formed in the connection region 31, and a plurality of touch electrodes 320 are formed in the identification region 32,

The touch electrodes 320 is formed by patterning indium tin oxide (ITO), and includes a plurality of driving electrodes 321 arranged as an array spacing distribution, a plurality of induction electrodes 322 are interlaced and insulated with the plurality of driving electrodes 321, both of the driving electrodes 321 and the induction electrodes 322 are rhombus shapes.

In one embodiment, the driving electrodes 321 and the induction electrodes 322 are arranged in a same layer, the two adjacent induction electrodes 322 are connected, and a plurality of fractures are formed between the induction electrodes 322 and the driving electrodes 321, so that a plurality of induction capacitors are formed between the drive electrode 321 and the induction electrode 322. Two adjacent driving electrodes 321 are connected by a bridge by which the conductive bridge 323 insulated with the induction electrode 322 to realize the touch function by a mutual capacitance model.

The driving electrodes 321 are connected to the connection region 31 through a plurality of driving electrode wirings 3211, the induction electrodes 322 are connected to the connection region 31 through the induction electrode wirings 3221, and signals are transmitted by the connectors 310 in the connection region 31

In one embodiment, referring to FIG. 3b, the driving electrodes 321 and the induction electrodes are arranged in the same layer, an insulating layer 324 is formed on the driving electrodes 321 and the induction electrodes 322, and covers the driving electrodes 321 and the induction electrodes 322, a plurality of through holes 3241 are formed in the insulating layer 324 corresponding to two adjacent driving electrodes 321. The insulating layer 324 is made of silicon nitride etc.

A plurality of conductive bridges 323 are formed on the insulating layer 324, the conductive bridges 323 are connected to two adjacent driving electrodes 321 through the through holes 3241. The conductive bridges 323 are made of titanium, aluminum or other metals.

A passivation layer 325 is formed on the insulating layer 324, and the passivation layer 325 covers the conductive bridge 323.

In one embodiment, referring to FIG. 2, the polarized light touch device further includes a first protective layer 40 and a second protective layer 50. The first protective layer 40 is formed on a surface of the polarizer layer 20 facing away from the substrate 10, the second protective layer 50 is formed on a surface of the touch layer 30 facing away from the substrate 10, the first protective layer 40 and the second protective layer 50 are used to protect the polarized light touch device.

In the application, both of the polarizer layer 20 and the touch layer 30 are prepared on the substrate 10, compared with prior art, it does not need a bonding layer located between the polarizer layer 20 and the substrate 10, thereby reducing a thickness of one bonding layer; as the phase compensation film 201 is prepared by a coating method, so one bonding layer located between the phase compensation film 201 and the substrate 10 is reduced; as the polarizer function film 202 is prepared by a coating method, the isolation layer only needs to be prepared on the upper surface after coating, thus reducing one isolation layer located between the polarizer function film 202 and the phase compensation film 201; at the same time, the thickness of the polyvinyl alcohol film layer prepared by a coating method is significantly reduced than the thickness of the polyvinyl alcohol film layer made by stretching. In the above way, compared with prior art, a thickness of three bonding layers and one isolation layer is reduced, and the thickness of polarizer function film is also reduced, so as to achieve the overall thickness of the polarized light touch device.

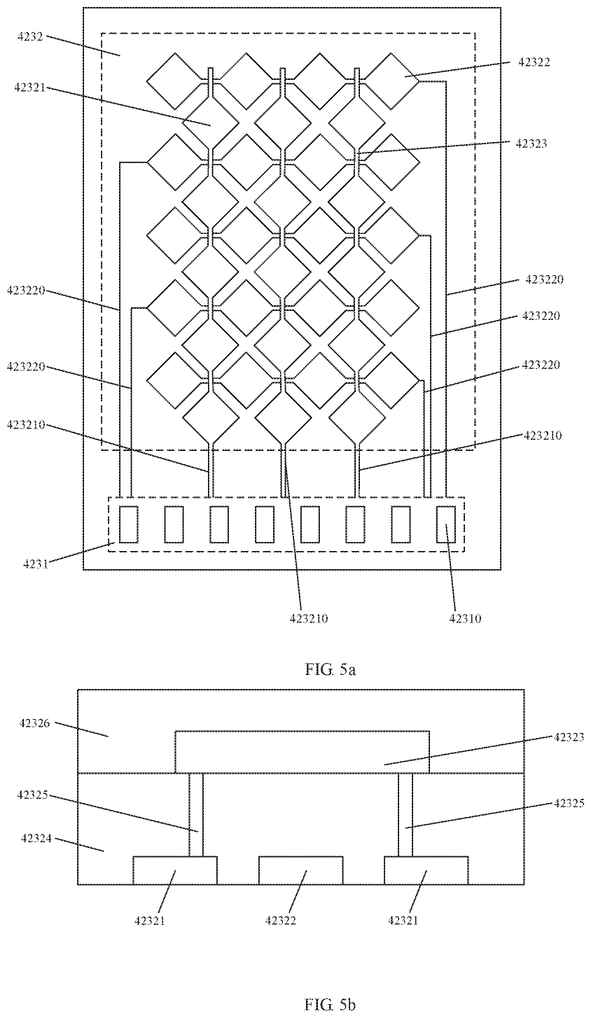

At the same time, in one embodiment, the application provides a flexible display device, referring to FIG. 4, the flexible display device includes:

A flexible display panel 41;

A polarized light touch device 42, formed on the light direction of the flexible display panel 41; and

a protective cover 43;

The polarized light touch device includes: a substrate 421; a polarizer layer 422 formed on a surface of the substrate 421 facing away from the flexible display panel; a touch layer 423 formed on a surface of the substrate 421 facing the flexible display panel.

The application provides a flexible display device, the polarized light touch device includes a substrate; a polarized light layer formed on a first surface of the substrate; a touch layer formed on a second surface of the substrate. The touch layer and the polarized layer get together to one piece structure as the polarized light touch device to omit an extra adhesive formed between the touch layer and the polarized light layer, to reduce an overall thickness of the flexible display device, and to make it more thinner.

In one embodiment, referring to FIG. 4, the flexible display panel 41 and the polarized light touch device 42 are bonded by a first glue layer 44, the polarized light touch device 42 and the protective cover 43 are bonded by a second glue layer 45. In the present embodiment, the first glue layer 44 and the second glue layer 45 are optically clear adhesive (OCA, the optical acrylic glue is made without substrate, and then laminated with a layer of release film on the bottom of the upper and lower layer, is a kind of double-sided glue tape without matrix material) optical cement.

In one embodiment, referring to FIG. 4, the flexible display device further includes a flexible printed circuit board 46, the flexible display printed circuit board 46 includes a plurality of driving chips (not shown in figure), and the driving chips are electrically connected to the polarized light touch devices 42.

In one embodiment, the flexible display panel 41 is Active-matrix organic light emitting diode (AMOLED) display panel.

In one embodiment, the substrate 421 is made of COP, PET etc. to ensure the polarized light touch devices having a better bending characteristic.

In one embodiment, referring to FIG. 4, the polarizer layer 422 is formed on the first surface of the substrate 421 and includes a phase compensation film 4221 and a polarizer function film 4222, and the phase compensation film 4221 is formed on the first surface of the substrate 421.

In one embodiment, the phase compensation film 4221 is based on the substrate 421 and directly formed on the substrate 421 by a coating process, that is, the phase compensation film 4221 is connected to the substrate 421 without a coating glue layer, but the phase compensation film 4221 is directly formed on the substrate 421. The phase compensation film 4221 is quarter wavelength film.

The polarizer function film 4222 plays a major role in polarizing in the polarizer layer 422, which determines a polarizing performance and transmittance of the polarizer layer 422, at the same time, the polarizer function film 4222 is also a major part of affecting a tone and optical durability of the polarizer layer 422.

The polarizer layer 422 includes a bonding layer 4223, the bonding layer 4223 is formed on a side surface of the phase compensation film 4221 facing away from the substrate 421, in this embodiment, the bonding layer 4223 is made of a pressure sensitive adhesive, because the pressure sensitive adhesive has characteristics of low elastic modulus and high bending, it can be used to support and protect the polarizer function film 4222.

In one embodiment, the polarizer function film 4222 is polyvinyl alcohol film. The polyvinyl alcohol film is formed by applying light alignment technique to arrange double absorption dye molecules and obtain a high D value, and then the dye molecules are coated on the bonding layer 4223, a thickness of the polyvinyl alcohol film is less than 2 micrometers. Because the polarizer function film 4222 is prepared by a coating method, the thickness of the film layer is obviously reduced compared with the prior polyvinyl alcohol by a stretching method.

Because the polyvinyl alcohol material is easy to absorb water and fade, so it needs to form a material with a good optical uniformity and transparency on one side surface of the polarizer function film 4223 facing away from the bonding layer to isolate water and air, to protect the polarizer function film 4222, and to prevent the polarizer function film 4223 from losing polarizer performance due to water absorption and fading.

Therefore, the polarizer layer 422 further includes an isolation layer 4224, the isolation layer 4224 is formed on one side surface of the polarizer function film 4222 facing away from the bonding layer 4223 to isolate water and air, and to protect the polarizer function film 4222. In the present embodiment, the isolation layer 4224 is made of cellulose triacetate.

In prior art, the polarizer function film is formed by stretching a polyvinyl alcohol to form a film, and then bonds to the phase compensation film, therefore, it is necessary to prepare an isolation layer on the upper and lower surfaces of the polarizer function film firstly to isolate water and air before bonding.

Compared with prior art, the polarized light touch device is provided by the application, as the polarizer function film 4222 is formed by a coating method, so only needs to prepare an isolation layer on the upper surface after coating, that is, one isolation layer is reduced between the polarizer function film 4222 and the phase compensation film 4221; at the same time, the thickness of the polyvinyl alcohol film layer prepared by a coating method is significantly reduced than that of the polyvinyl alcohol film layer made by stretching, so as to achieve the overall thinning of the polarized light touch device.

The touch layer 423 is formed on the second surface of the substrate 421, and the specific structure of the touch layer 30 is shown in FIG. 5a and FIG. 5b.

Referring to FIG. 5a, the touch layer 423 includes a connection region 4231 and an identification region 4232, a plurality of connectors 42310 are formed in the connection region 4231, and a plurality of touch electrodes 42320 are formed in the identification region 4232.

The touch electrodes 42320 is formed by patterning indium tin oxide (ITO), and includes a plurality of driving electrodes 42321 arranged as an array spacing distribution, a plurality of induction electrodes 42322 are interlaced and insulated with the plurality of driving electrodes 42321, both of the driving electrodes 42321 and the induction electrodes 42322 are rhombus shape.

The driving electrodes 42321 and the induction electrodes 42322 are arranged in the same layer, the two adjacent induction electrodes 42322 are connected, and a plurality of fractures are formed between the induction electrodes 42322 and the driving electrodes 42321, so that a plurality of induction capacitors are formed between the drive electrode 42321 and the induction electrode 42322. Two adjacent driving electrodes 42321 are connected by a bridge which the conductive bridge 42323 insulated with the induction electrode 42322 to realize the touch function by a mutual capacitance model.

The driving electrodes 42321 are connected to the connection region 4231 through a plurality of driving electrode wirings 423210, the induction electrodes 42322 are connected to the connection region 4231 through induction electrode wirings 423220, the connectors 42310 of the connection region 4231 are electrically connected to the driving chips of the flexible printed circuit board 46 to complete signal transmission.

Referring to FIG. 5b, the driving electrodes 42321 and the induction electrodes 42322 are arranged in the same layer, an insulating layer 42324 is formed on the driving electrodes 42321 and the induction electrodes 42322, and covers the driving electrodes 42321 and the induction electrodes 42322, a plurality of through holes 42325 are formed in the insulating layer 42324 corresponding to two adjacent driving electrodes 42321. The insulating layer 42324 is made of silicon nitride etc.

A plurality of conductive bridges 42323 are formed on the insulating layer 42324, the conductive bridges 42323 are connected to two adjacent driving electrodes 42321 through the through holes 42325. The conductive bridges 42323 are made of titanium, aluminum or other metals.

A passivation layer 42326 is formed on the insulating layer 42324, and the passivation layer 42326 covers the conductive bridge 42323.

When the polarized light touch device 42 is not bonding together with the flexible display panel 41 and the protective cover 43, a first protective layer and a second protective layer (not shown in the figure) are formed on an upper surface and a lower surface of the polarized light touch device 42 to protect the polarized light touch device 42.

In the application, both of the polarizer layer 422 and the touch layer 423 are prepared on the substrate 421, compared with prior art, it does not need a bonding layer located between the polarizer layer 422 and the substrate 421, thereby reducing a thickness of one bonding layer; as the phase compensation film 4221 is prepared by a coating method, so one bonding layer located between the phase compensation film 4221 and the substrate 421 is reduced; as the polarizer function film 4222 is prepared by a coating method, the isolation layer only needs to be prepared on the upper surface after coating, thus reducing one isolation layer located between the polarizer function film 4222 and the phase compensation film 4221; at the same time, the thickness of the polyvinyl alcohol film layer prepared by a coating method is significantly reduced than the thickness of the polyvinyl alcohol film layer made by stretching. In the above way, compared with prior art, a thickness of three bonding layers and one isolation layer is reduced, and the thickness of polarizer function film is also reduced, so as to achieve the overall thickness of the polarized light touch device.

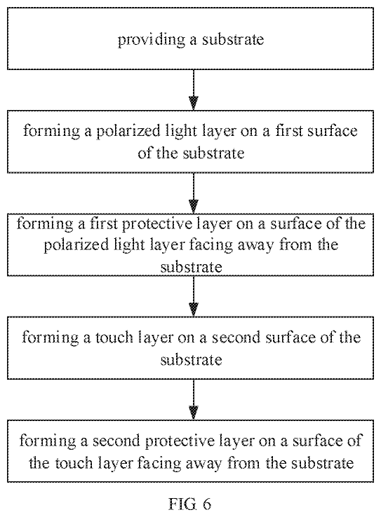

At the same time, in one embodiment, the application further provides a method for manufacturing a flexible display device, referring to FIG. 6, the method includes:

S1: providing a flexible display panel.

The substrate is made of COP, PET or CPI etc., so as to ensure that the polarized light touch device has better bending characteristics.

S2: forming a polarizer layer on a first surface of the substrate.

In one embodiment, the step of S2 includes:

A phase compensation film is coated on the first surface of the substrate firstly, the phase compensation film is based on the substrate and directly formed on the substrate by a coating process, that is the phase compensation film is connected to the substrate without coating a glue layer, but the phase compensation film is directly formed on the substrate. The phase compensation film is quarter wavelength film.

And then a bonding layer is coated on the phase compensation film, in one embodiment, the bonding layer is made of a pressure sensitive adhesive.

Finally, a polarizer function film is coated on the bonding layer, in one embodiment, the polarizer function film is a polyvinyl alcohol film. Because the polyvinyl alcohol material is easy to absorb water and fade, so it needs to form a material with a good optical uniformity and transparency on one side surface of the polarizer function film 202 facing away from the bonding layer to isolate water and air.

Therefore, in one embodiment, an isolation layer is formed on the polarizer function film after coating a polarizer function film, and the isolation layer is used to protect the polarizer function film and to prevent the polarizer function film from losing a polarizing performance due to water absorption and fading.

As the polarizer function film is formed by a coating method, and compared with prior art, the thickness of the polyvinyl alcohol film layer is significantly reduced.

S3: forming a first protective layer on the surface of the polarizer function film facing away from the substrate.

The first protective layer is used to protect the polarized light touch device, when the polarizer touch control component is needed to be bonded with other display devices, the first protective component is removed firstly, and then which is bonded with other display devices.

S4: forming a touch layer on a second surface of the substrate.

In one embodiment, the step of S4 includes:

A connection region and an identification region are formed on the surface of the substrate firstly, a plurality of touch electrodes are formed in the identification region, and a plurality of connectors are formed in the connection region to form a touch layer finally.

The touch electrodes include a plurality of driving electrodes and a plurality of induction electrodes, the driving electrodes and the induction electrodes are prepared in the same layer. The two adjacent induction electrodes are connected, and a plurality of fractures are formed between the induction electrodes and the driving electrodes, so that a plurality of induction capacitors are formed between the drive electrode and the induction electrodes.

After the driving electrodes and the induction electrodes are arranged in the same layer, then an insulating layer is formed to cover the driving electrodes and the induction electrodes, a plurality of through holes are formed in the insulating layer corresponding to two adjacent driving electrodes. The insulating layer is made of silicon nitride etc.

A plurality of conductive bridges are formed on the insulating layer, the conductive bridges are connected to two adjacent driving electrodes through the through holes. Two adjacent driving electrodes are connected by a bridge which the conductive bridge insulated with the inductive electrode, and to realize the touch function by a mutual capacitance method. The conductive bridges are made of titanium, aluminum or other metals.

Finally, a passivation layer is formed on the insulating layer, and the passivation layer covers the conductive bridge.

In one embodiment, the metal film layer, the insulating layer and the passivation layer are deposited by a chemical vapor deposition process and a sputtering process etc., and a mask plate is applied to form the contact electrodes, the conductive bridges and the through holes by steps of exposure, development and etching etc.

The driving electrodes are connected to the connection region through a plurality of driving electrode wirings, the induction electrodes are connected to the connection region through induction electrode wirings, and signals are transmitted by the connectors in the connection region.

S5: forming a second protective layer on a surface of the touch layer facing away from the substrate.

The second protective layer is used to protect the polarized light touch devices, when the polarized light touch devices is needed to be bonded with other display devices, the second protective component is removed firstly, and then which is bonded with other display devices.

The application provides a polarized light touch device, a method for manufacturing the polarized light touch device, and a flexible display device, the polarized light touch device includes a substrate; a polarized light layer formed on a first surface of the substrate; a touch layer formed on a second surface of the substrate; a first protective layer formed on a surface of the polarized light layer facing away from the substrate; and a second protective layer formed on a surface of the touch layer facing away from the substrate. The touch layer and the polarized layer get together to one piece structure as the polarized light touch device to omit an extra optical clear adhesive (OCA) formed between the touch layer and the polarized light layer, to reduce an overall thickness of the flexible display device, and to make it more thinner.

According to the above embodiments:

The application provides a method for manufacturing a polarized light touch device, the polarized light touch device manufactured by the method includes a substrate; a polarized light layer formed on a first surface of the substrate; a touch layer formed on a second surface of the substrate; a first protective layer formed on a surface of the polarized light layer facing away from the substrate; and a second protective layer formed on a surface of the touch layer facing away from the substrate. The touch layer and the polarized layer get together to one piece structure as the polarized light touch device to omit an extra optical clear adhesive (OCA) formed between the touch layer and the polarized light layer, to reduce an overall thickness of the flexible display device, and to make it more thinner.

As is understood by persons skilled in the art, the foregoing preferred embodiments of the application are illustrative rather than limiting of the application. It is intended that they cover various modifications and that similar arrangements be included in the spirit and scope of the application, the scope of which should be accorded the broadest interpretation so as to encompass all such modifications and similar structures.

What is claimed is:

1. A polarized light touch device, comprising:
a substrate;
a polarized light layer formed on a first surface of the substrate;
a touch layer formed on a second surface of the substrate;
a first protective layer formed on a surface of the polarized light layer facing away from the substrate; and
a second protective layer formed on a surface of the touch layer facing away from the substrate.

2. The polarized light touch device of claim 1, wherein the polarized light layer comprises a phase compensation film and a polarized light function film, the phase compensation film is formed on the substrate.

3. The polarized light touch device of claim 1, wherein the phase compensation film is a quarter wavelength film.

4. The polarized light touch device of claim 2, wherein the polarized light function film is polyvinyl alcohol film.

5. The polarized light touch device of claim 1, wherein the touch layer comprises a connection region and an identification region, a plurality of touch electrodes are formed in the identification region, a plurality of connectors are formed in the connection region.

6. The polarized light touch device of claim 5, wherein the touch electrodes comprises a plurality of driving electrodes and a plurality of induction electrodes, the driving electrodes and the induction electrodes are arranged in a same layer.

7. A flexible display device, comprising:
a flexible display panel;
a polarized light touch device formed on a light direction of the flexible display panel; and
a protective cover;
wherein the polarized light touch device comprises:
a substrate;
a polarized light layer formed on a surface of the substrate facing away from the flexible display panel;
a touch layer formed on a surface of the substrate facing the flexible display panel.

8. The flexible display device of claim 7, wherein the polarized light layer comprises a phase compensation film and a polarized light function film, the phase compensation film is formed on the substrate.

9. The flexible display device of claim 8, wherein the phase compensation film is a quarter wavelength film.

10. The flexible display device of claim 8, wherein the polarized light function film is polyvinyl alcohol film.

11. The flexible display device of claim 7, wherein the touch layer comprises a connection region and an identification region, a plurality of touch electrodes are formed in the identification region, a plurality of connectors are formed in the connection region.

12. The flexible display device of the claim 11, wherein the touch electrodes comprises a plurality of driving electrodes and a plurality of induction electrodes, the driving electrodes and the induction electrodes are arranged in a same layer.

13. The flexible display device of the claim 11, wherein the flexible display device comprises a flexible printed circuit board, the flexible printed circuit board comprises driving chips, the driving chips are electrically connected to the connectors.

14. A method for manufacturing a polarized light touch device, comprising:
providing a substrate;
forming a polarized light layer on a first surface of the substrate;
forming a first protective layer on a surface of the polarized light layer facing away from the substrate;
forming a touch layer on a second surface of the substrate; and
forming a second protective layer on a surface of the touch layer facing away from the substrate.

15. The method for manufacturing a polarized light touch device of claim 14, wherein a step of forming a polarized light layer on a first surface of the substrate comprises:
coating a phase compensation film on the substrate;
coating an adhesive layer on the phase compensation film; and
coating a polarized light function film on the adhesive layer to form a polarized light layer.

16. The method for manufacturing a polarized light touch device of claim 15, wherein a step of coating a phase compensation film on the substrate comprises:
coating a quarter wavelength film on the substrate.

17. The method for manufacturing a polarized light touch device of claim 15, wherein a step of coating an adhesive layer on the phase compensation film comprises:
coating a pressure sensitive adhesive on the phase compensation film.

18. The method for manufacturing a polarized light touch device of claim 15, wherein a step of coating a polarized light function film on the adhesive layer comprises:
coating a polyvinyl alcohol film on the adhesive layer.

19. The method for manufacturing a polarized light touch device of claim 14, wherein a step of forming a touch layer on a second surface of the substrate comprises:
forming a connection region and an identification region on a second surface of the substrate;
forming a plurality of touch electrodes in the identification region; and
forming a plurality of connectors in the connection region.

20. The method for manufacturing a polarized light touch device of claim 19, wherein a step of forming a plurality of touch electrodes in the identification region comprises:
forming a plurality of driving electrodes and a plurality of induction electrodes, wherein the driving electrodes and the induction electrodes are arranged in a same layer.
